(19) United States
(12) Patent Application Publication
(10) Pub. No.: US 2009/0277495 A1
(43) Pub. Date: Nov. 12, 2009

(54) CONCENTRATED PV SOLAR POWER STACK SYSTEM

(76) Inventors: Mihai Talaba, Langley (CA); Teodor Adrian Talaba, Langley (CA); Ron W. Britton, Naramata (CA); Codrin Talaba, Langley (CA)

Correspondence Address: MIHAI TALABA, 8846 - 212A STREET, LANGLEY, BC, V1M 2J9, CA

(21) Appl. No.: 12/118,718

(22) Filed: May 11, 2008

(51) Int. Cl. H01L 31/042

(52) U.S. Cl. 136/246

(57) ABSTRACT

The concentrated PV solar power stack system includes a solar concentration assembly, HC sunlight transmission light pipe and a LEC stack assembly holding a plurality of light-to-electricity conversion (LEC) cells inside a compact weatherproofed housing enclosure. Each single LEC cell includes one LD panel having one light-emitting side and one PV solar panel adjoining the said LD panel; alternatively, a double-sided LD panel capable of emitting solar radiation evenly on both sides and two adjoining PV panels on each of the outer side of the said LD panel form a double LEC cell. A spectral & thermal conditioning system of the HC solar radiation beam represented by a combination of spectral cooling and heat sink devices reduces the thermal load in the LEC stack assembly and also improves the its light-to-electricity conversion rate.

### REFERENCES CITED

US PATENT DOCUMENTS

| | | | |
|---|---|---|---|
| 3,314,331 | April 1967 | Wiley | 88-24 |
| 3,379,394 | April 1968 | Bialy | 244/1 |
| 4,023,368 | May 1977 | Kelly | 60/698 |
| 4,153,475 | May 1979 | Hilder et al | 136/89 |
| 4,716,258 | December 1987 | Murtha | 136/246 |
| 4,026,267 | May 1977 | Coleman | 126/270 |
| 4,234,907 | November 1980 | Daniel | 362/32 |
| 4,516,314 | May 1985 | Sater | 29/572 |
| 4,529,830 | July 1985 | Daniel | 136/246 |
| 4,539,625 | September 1985 | Bornstein et al | 362/32 |
| 4,798,444 | January 1989 | McLean, | 350/96.24 |
| 4,927,770 | May 1990 | Swanson | 437/2 |
| 4,943,125 | July 1990 | Laundre et al | 350/96.1 |
| 5,096,505 | March 1992 | Fraas et al | 136/246 |
| 5,217,539 | June 1993 | Fraas et al | 136/246 |
| 6,091,020 | July 2000 | Fairbanks et al | 136/259 |
| 6,252,155 | June 2001 | Ortabasi | 136/246 |
| 6,700,055 | March 2004 | Barone | 136/246 |
| 6,895,145 | May 2005 | Ho | 385/35 |
| 7,081,584 | July 2006 | Mook | 136/246 |
| 7,190,531 | March 2007 | Dyson et al | 359/742 |

### OTHER PUBLICATIONS

1. X. Ning, J. O'Gallagher, and R. Winston, “Optics of two-stage photovoltaic concentrators with dielectric second stages”, Appl. Opt. 26(7), 1207-1212 (1987)
2. R. M. Swanson, “The Promise of Concentrators”, Prog. Photovolt. Res. Appl., 8, 93-111 (2000)
3. Geoffrey Kinsey, “Concentrating PV: Getting More From Less”, Solar Power 2007 Conference, California, USA, Sep. 24-27, 2007

### TECHNICAL FIELD

This invention relates to means for sunlight concentration, remote transmission, distribution and direct photovoltaic conversion of the concentrated solar radiant energy into electricity. More particularly, the present invention is concerned with sunlight collection through a solar concentrator having adequate heat dissipation means, high concentration sunlight transmission through light pipes, even distribution of sunlight to a plurality of light distribution panels and direct conversion of the light to electricity by a plurality of PV solar panels assembled in a stack configuration, in a consecutive PV solar panel-light distribution panel paired pattern.

### BACKGROUND OF THE INVENTION

Nowadays, the significant surge in demand for alternative sources of energies (i.e., wind, solar, hydro, etc.) has created opportunities for fast development of the global alternative energy infrastructure, measurable at the giga-watts levels. While the applications in solar power generation have been lagging behind those in the wind power sector due to much higher initial capital costs and lower performance efficiencies, recent increases in demand for solar power have created an unprecedented interest in alternative solar technologies. The construction of new solar power plants has intensified, leading to a subsequent boost in manufacturing capacities worldwide and, thus, to significant reductions in costs—with the shift towards an economy of scale. Measurable drops in the PV solar panel manufacturing and installation costs resulted in comparable reductions of the overall power plant costs. However, increase in performance of the PV solar panel modules and improvements of the solar power system effectiveness through technical innovations have a more direct and stronger impact on reducing costs by allowing for a lower number of PV solar panels for a preset power output, thus a smaller footprint of the respective PV solar installation. To this end, new technological advances in the rapidly growing field of concentrated PV cells underline a genuine option for significant reductions in PV cell surface area per kW of electrical output and, therefore, a real possibility to produce electricity at competitively lower costs.

Notwithstanding the progress thus far achieved, the conventional technologies used for direct conversion of sunlight into electricity include, for the most part: i) building-integrated “flat-plate” PV solar panels (rooftops), and ii) ground-based continuous flat PV arrays, both depending on direct or normal exposure to solar radiant energy to produce their rated power outputs. Most of these conventional set-ups pose several common yet serious limitations especially when used in medium- and large-scale applications (i.e., at the hundreds of kWs and MWs power output levels):
The conventional flat PV solar panels operate at conversion efficiencies ranging from 12% to 18% and, therefore, a typical solar utility plant requires a considerable number of panels as well as a large surface area to install them—for example, a 500 kW solar power plant would require the area of a football field (i.e., 5,353 m²) and about 2,500 of the better performing PV flat panels currently available on the market (i.e., 16%-18% efficiency and 200 W power output/panel);
The PV solar panels require reliable weather-proofing to protect them from the long-term deleterious effects of the weather and also large supporting metal structures occupying significant areas of land for installing hundreds of flat PV panels needed for the respective solar power plants. That adds considerable installation, maintenance & operation costs to the already high costs of the flat PV panels and their related supporting infrastructure;
The effectiveness of the fixed solar panel arrays is seriously limited by receiving optimum solar energy only for a portion of the day, while the sun-following solar panels receive maximum exposure to the sun's radiant energy continuously during the entire day. However, a sun-following tracking system represents a significant expense added to a fixed solar panel power system and its operation also requires parasitic power as a portion of its own production of electricity. As a result, the implementation of a tracking system must be carefully weighted against its actual contribution towards the improvement of the energy production capacity factor in the respective solar power plant;
Most of the present ground-based solar power plants are placed in open flat lands in a fixed array arrangement of the PV panels to make optimum use of the solar radiant energy. While this set-up may be practical for direct solar electrical conversion in remote and rural areas, it does not provide for a compatible economical solution to highly populated urban areas where land is at premium and electrical power is always in large demand. Conversely, the use of remote or rural land for the construction of PV solar power plants to service urban areas may increase the overall energy production costs up to 20%, due to added costs and further power losses through extra transmission and distribution installations required to deliver electricity.

Early attempts to reduce the footprint of the PV solar installations were directed at highly compacted solar panel arrangements having multiple closely spaced solar cells mounted to function through direct interaction with incident sunlight. U.S. Pat. No. 4,023,368, evidenced the concept of a three-dimensional (3D) solar panel geometry allowing for a 33% assembly foot-print reduction by using side reflectors to direct incident sunlight onto the underside, unexposed solar cells. U.S. Pat. No. 4,153,475, presents a more compact power-generating system having a 3D-stacked solar panel arrangement, so that direct sunlight received from the side edges of the solar panels is redirected to the facing surfaces of each of the solar panels.

Most of the technical innovations at the system level focus on effective sunlight concentration technologies. It is known to the art that the cost of producing electricity with PV cells can be considerably reduced when a large area of sunlight is concentrated upon a small area of a PV cell, which is currently the most expensive component of the system on a per unit area basis. At the same time, photovoltaic materials are more efficient at higher solar intensity levels than that of ordinary sunlight. However, one important drawback associated with current use of concentrated solar energy with PV cells is the heat build-up due to their inherent low efficiencies—i.e., only a portion of the solar energy is converted into useful (electrical) energy, the rest being absorbed as heat throughout the PV cell. It is critical that the PV cells operate within strict temperature limits in order to maintain their performance at maximum efficiency levels—therefore, adequate cooling is essential (see, U.S. Pat. No. 7,081,584). Concentrating solar radiation devices can use refractive optics (e.g., parabolic mirrors, through, cone and trapezoidal-shaped mirrors), and/or reflective optics (lens) and/or a combination of different such optical elements in one or multi-stage arrangements, to yield high concentration ratios on the order of 50× or more suns. Precise alignments of the concentrators with the sun through adequate tracking systems can increase the energy generation up to 30%.

The combination of solar energy concentrators with effective means of high concentration (HC) solar radiation transmission to remote locations has opened the doors to a wide range of applications from architectural hybrid solar lighting to a variety of utilization devices including solar conversion systems, some of which are illustrated in the following examples. The optical solar energy converter disclosed in U.S. Pat. No. 3,379,394 provides an early example of the use of fiber optics to receive and transmit solar radiation collected from the external surface of a satellite remotely to a thermoelectric unit inside it. U.S. Pat. No. 4,026,267 describes a solar energy collection that utilizes wide-angle lens for focusing incident solar radiation on the ends of bundles of optical fibers, which transmit the HC solar radiation to a storage and/or utilization site, primarily in either a heat sink or a PV cell system. U.S. Pat. No. 4,539,625 discloses a combined lighting system for a building interior including a stack of luminescent solar concentrators, an optical conduit made of preferably optical fibers for transmitting collimated daylight to a hybrid illumination fixture for receiving daylight at one end and artificial light from a source at the other end. U.S. Pat. No. 4,529,830 presents a practical means for transmitting concentrated sunlight from a solar radiation concentrating system through a relatively small number of optical fiber bundles to various solar utilization devices. In one application, concentrated sunlight is transmitted through a number of light-emitting fabric pieces to solar cells positioned above and below of each light-emitting fabric, to form a light-to-electricity converter. U.S. Pat. No. 6,695,145 presents a solar concentrator system including an array of light converging spherical lens and optical fibers, which transmit the concentrated sunlight to hybrid solar lighting and/or heating devices. The spherical lenses provide the advantage of a multidirectional light collection system that is effective in converging light rays without the need for realignment through a tracking system.

Recent innovations in the field of concentrated photovoltaics (CPV) leading to high performance solar concentrators and new generations of high efficiency PV cells have increased the potential to lower costs of the production of electricity. By using cheap, well-designed optical devices that make the high performance solar concentrators capable to intensify the incident solar radiation from the strength of one sun to the order of 50-1,000 or more suns, the required active area of expensive semiconductor material in the PV cells is greatly reduced. However, the CPV are faced with the strong challenges of having to maximize their efficiency and lifetime while operating at elevated temperatures and high concentration solar radiation. Some of the early CPV cells, first used in space applications, are described in a number of U.S. patents including U.S. Pat. Nos. 5,096,505; 5,217,539; 6,091,020 and 6,252,155. The use of high performance GaAs and AlGaAs PV cells encapsulated with materials having thermal and mechanical stability (i.e., TiN, TiWN, TaN) allowed for continuous use of the cells in harsh space environment at ambient temperatures above 300° C. and at 50× or more suns concentrations, while maintaining sustainable energy conversion levels for the long-term space station operation.

Intense development efforts towards improving performance of the CPV solar cells for earth-bound applications have made possible the realization of 25%-42% efficiency levels under high sunlight concentrations with PV cells of the 3^{rd} and 4^{th} generation (i.e., CPV cells and, respectively, multi-junction PV cells). In the 1980s, innovations in Si-based PV cells led to the development of high intensity multi-junction (MJ) PV cells (i.e., capable of 40 W/cm² output power density and an efficiency of 20%) described in a series of U.S. patents by Sater, including the U.S. Pat. No. 4,516,314. In addition, R. M. Swanson proposed in U.S. Pat. No. 4,927,770, a point contact silicon solar cell capable of performing with solar concentrators, an idea that is also described in several other U.S. patents included by reference in U.S. Pat. No. 7,081,584. The current record of the Si-based PV cells conversion efficiency is 25%, while the commercially available flat PV panels operate at a range of efficiencies from 12% to 20%, depending on the quality and thickness of the Si wafer used in their construction. Efforts to increase the conversion efficiency of MJ PV cells led to utilization of Periodic III-V semiconductor materials to capture an expanded range of photon energies, therefore a wider spectrum of the sunlight radiation converted to electricity. Technological innovations led to MJ non-Si PV cells including GaAs, GaAs/GaSb, GaInP, GaAs/Ge, CuInSe₂, or the like, which have higher efficiencies than the Si-based PV cells, and are also capable to operate at temperatures higher than 100° C. For example, Boeing-Spectrolab, a major player in developing high efficiency MJ PV cells, has recently reported their record conversion efficiency of 40% in the multi-junction PV cell, with the expectation to reach the 43% level in the next two years.

The biggest potential advantage of CPVs is the promise of lower costs than flat PV panels, especially in utility applications, due to better aperture efficiencies (i.e., Wp/m² of module) and greater energy densities (i.e., kWh/m² of land or roof space) of MJ PV cells. In addition, CPVs with high efficiency MJ PV cells would reduce dependence on solar-grade silicon in the production of PV panels. In spite of a reduction in the silicon consumption brought about by lower wafer thickness and yield improvements, there is still a considerable gap between supply and demand of silicon, which maintains the market prices of the Si-based PV cells high, mainly due to fast expanding flat PV panel markets as well as the inability of the manufacturing sector to develop new facilities fast enough to match increasing demand.

The biggest challenges of the CPV are the pointing accuracy to the sun and good thermal management in the area of the high efficiency MJ PV cells. The high concentration photovoltaic (HC PV) cells require precise alignment of the optical devices with the sun—a flat PV panel is able to perform at 90% of its maximum power output even with 20 degrees angular error of its tracking system, while an angular error greater than ±2 degrees in a CPV assembly would render the system's power generation essentially down to zero (see, U.S. Pat. No. 6,091,020). In addition, flat panels can take advantage of the diffusively reflected sunlight from the environment, which the CPV cannot access—for example, if a flat PV panel receives 1,000 W/m² in total irradiance, a CPV can access only 850 W/m², which is direct normal irradiance. Therefore, with the CPV systems, accurate sun tracking is crucial. Thermal management of the CPV systems has all the thermal challenges of the flat PV systems and, in addition, the challenge of having to conduct heat away from a considerably smaller area of the MJ PV cells than that of the conventional flat PV panels. It is beneficial to keep the MJ PV cells from overheating to avoid a decrease in cell's efficiency and to also prevent thermal stresses that cause interconnect-failures. Several cooling methods can be employed to effectively combat heat build-up in a CPV system including passive cooling heat sinks, active heat sinks (e.g., water cooling) or spectral cooling, depending on the specifics of the system application and the best fit cooling option for the system integration.

### SUMMARY OF THE INVENTION

It is one object of this invention to provide a novel PV solar power system operated on remote concentrated sunlight that would share some of the benefits of the CPV and other solar power systems aforementioned as well as other benefits that will become evident as described below. The system of the illustrative embodiments of the present invention combines HC solar radiant energy collection and transmission technologies with a PV solar power system in a 3D-configuration for compact and modular implementation in portable and building-integrated applications

The concentrated PV solar power stack system according to aspects of the present invention comprises a solar collection and concentration assembly, a HC solar radiation transmission light pipe and a compact PV stack assembly, including a HC sunlight distribution panel system. While the system can be easily installed as a stand-alone portable/remote solar power system or incorporated in a building structure as a building-integrated power application, other possible applications are not excluded.

It is one object of this invention to effectively combine solar concentration means with HC sunlight transmission and light distribution means, and a 3D compact PV stack assembly (also, called LEC stack throughout the description of this invention) into one compatible and cost effective compact concentrated solar power stack system (also, called Concentrated PV solar power stack system throughout the description of this invention). The present invention enables the use of various solar collection and concentration devices as well as high efficiency PV panels to ensure the necessary high light-to-electricity (LEC) conversions in this solar power application, while giving the consumer a wider selection of system configurations, power outputs and economy.

It is another object of this invention to effectively include the LEC stack system for producing electricity in conjunction with the use of an intense beam of sunlight conducted through buildings by means of tubular mirrors, optic fibers, prisms and various geometrically-shaped mirrors to divide, channel, distribute, deflect, reflect and diffuse the said sunlight beam for hybrid solar lighting inside the said buildings.

Thus the present invention teaches a novel combination and arrangement of parts, either commercially available or specifically designed and described below. It should be understood that changes and variations may be made in the detailed design of the parts, including the solar concentration means, the HC sunlight transmission and light distribution devices and the compact 3D PV stack assembly, without departing from the spirit and scope of the invention as claimed.

### BRIEF DESCRIPTION OF THE DRAWINGS

The detailed description of the exemplary embodiments particularly refers to the accompanying figures/drawings, as follows:

FIG. 1A. is a schematic diagram of the conventional Flat PV Panel solar power system.

FIG. 1B. is a schematic diagram of an embodiment of a Concentrated PV solar power stack system according to one aspect of the present invention.

FIG. 2. is a block diagram of the Concentrated PV solar power stack system flow diagram of FIG. 1B.

FIG. 3A. is a schematic diagram of the Concentrated PV solar power stack system of FIG. 1B, including an LEC Stack assembly.

FIG. 3B. is an isometric view detailing the LEC Stack assembly configuration of FIG. 3A.

FIG. 4. is an isometric view detailing an OFLD panel suitable for incorporation into the Concentrated PV solar power stack system of FIG. 1B.

FIG. 5A. is an isometric view detailing an LB panel suitable for incorporation into the Concentrated PV solar power stack system of FIG. 1B.

FIG. 5B. is a reverse cross-sectional view of the LB panel of FIG. 5A intersected by cutting plane I-I.

FIG. 6A. is an isometric view of a PV panel with cooling plate suitable for incorporation into the Concentrated PV solar power stack system of FIG. 1B.

FIG. 6B. is an exploded isometric view of the PV panel with cooling plate of FIG. 6A.

FIG. 6C. is an isometric view detailing the underside of the cooling plate of FIG. 6A.

FIG. 7A. is an isometric view of a Single S-LEC cell with OFLD panel suitable for incorporation into the Concentrated PV solar power stack system of FIG. 1B.

FIG. 7B. is an exploded isometric view of a Single S-LEC cell with OFLD panel of FIG. 7A.

FIG. 8A. is an isometric view of a Double D-LEC cell with OFLD panel suitable for incorporation into the Concentrated PV solar power stack system of FIG. 1B.

FIG. 8B. is an exploded isometric view of a Double D-LEC cell with OFLD panel of FIG. 8A.

FIG. 9A. is an isometric view of a D-LEC/OFLD Stack assembly suitable for incorporation into the Concentrated PV solar power stack system of FIG. 1B.

FIG. 9B. is an isometric view detailing the LEC Stack inside the housing enclosure of the LEC Stack assembly of FIG. 9A.

### DETAILED DESCRIPTION OF THE INVENTION

While the invention is susceptible to various modifications and alternative forms, exemplary embodiments thereof have been shown by way of example in the drawings and will herein be described in detail. It should be understood, however, that there is no intent to limit the invention to the particular forms disclosed, but on the contrary, the intention is to cover all modifications, equivalents, and alternatives falling within the spirit and scope of the invention as defined by the appended claims.

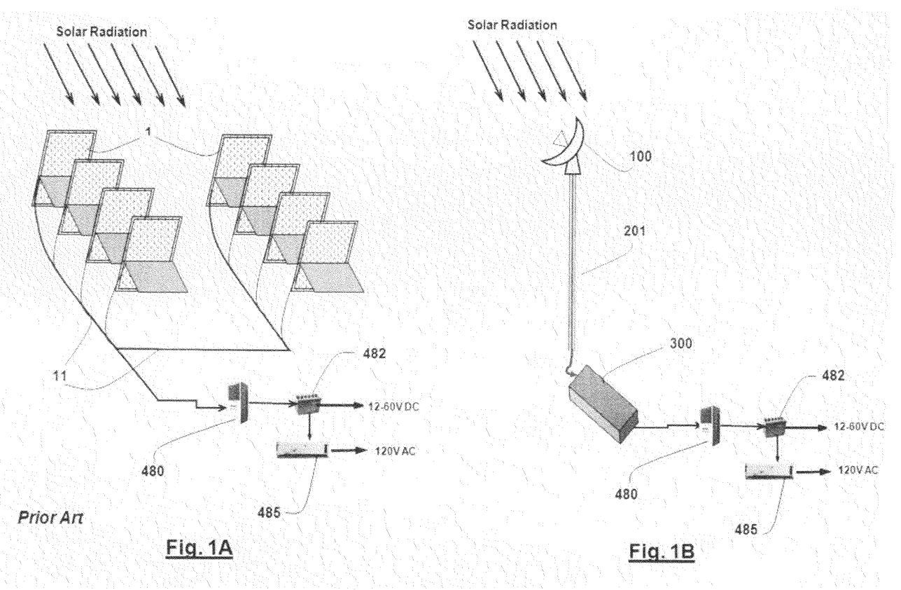

By way of overview, one basic difference between a compact concentrated PV solar power stack system according to this invention and a conventional flat PV panel solar power system becomes evident from the illustrations presented in FIG. 1A and FIG. 1B. Conventional PV solar power systems have flat PV panels indicated generally at 1 in FIG. 1A that can be installed either in a fixed arrays configuration or on solar tracking devices and placed either on the ground or on rooftops of buildings. Electrical cables 11 interconnect the flat PV panels and also conduct the electricity generated by the said PV panels to the balance-of-system (BOS). The BOS, comprised of a DC solar charge controller 480 and a battery bank 482, delivers 12-24-48-60V regulated DC power to consumers, or stores it for later use. An inverter 485 can also supply 120V AC to consumers, if so desired.

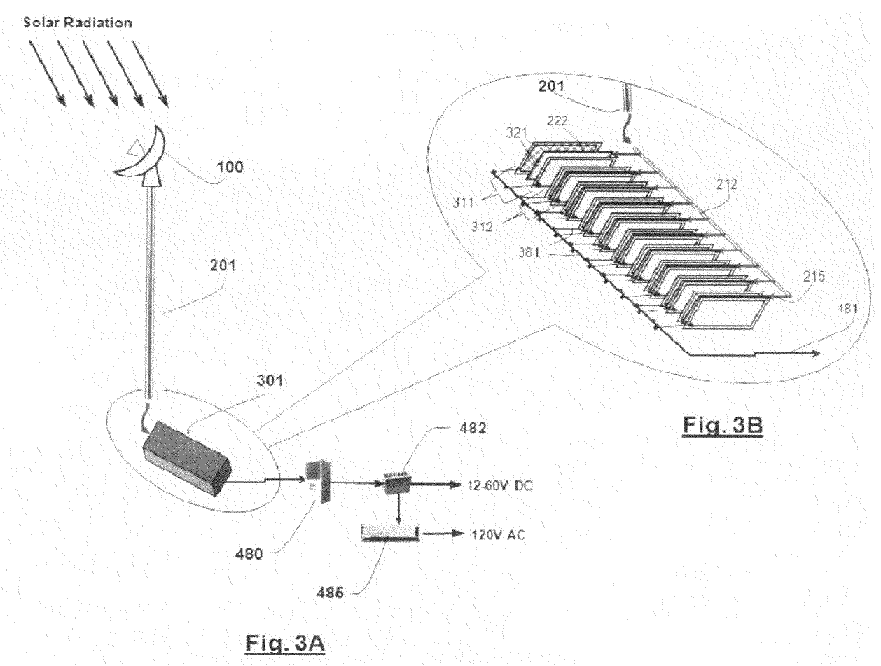

In contrast, FIG. 1B illustrates an embodiment of a Concentrated PV solar power stack system according to one aspect of the present invention, in which it can be seen that a solar concentrator assembly 100, a HC light pipe 201, and the LEC stack assembly 300 holding the light distribution (LD) panel system and all the necessary PV panels inside a compact weatherproofed enclosure, replace the traditional flat PV panels directly exposed to the sun from FIG. 1A. The light pipe 201 transmits the HC solar radiation from the solar concentrator assembly 100 to a plurality of LD panels 222 (see, FIG. 3B), which facilitate uniform illumination of all PV panels with HC solar radiation inside the LEC stack. The total surface of PV panels needed in the LEC stack to produce the rated power output depends both on the concentration power of the solar concentrator and also on the size and the conversion efficiency of the said PV modules.

Solar concentrators according to this invention can use a combination of reflective optics (e.g., parabolic mirrors, through, cone- and other geometrically-shaped mirrors), and/or refractive optics (lens) interconnected in one- or multi-stage arrangements to yield high concentration ratios of solar radiation on the order of 50× or more suns. Precise alignments of the concentrators with the sun through tracking systems can increase the entrapment of solar energy up to 30%. It is known that the best PV systems currently available in the market operate at 12%-20% electric conversion efficiencies and that leaves the remaining 88%-80% of solar radiation energy dissipated as wasted heat within the system—should this ineffective portion of the solar energy be all or in part removed from the system prior to its contact with the active surface of the PV cells, the performance of the said PV cells would improve considerably. In this context, the design of the solar concentration assembly according to the present invention allows for a combination of cooling methods to effectively combat heat build-up inside the LEC stack system, including spectral cooling and passive heat sinks in conjunction with active heat sink capabilities (especially in higher power outputs systems). Considering the technical and physical constraints of the conventional heat sink, especially in the compact power solar applications, spectral cooling can be employed effectively in removing the UV & IR radiations out of the HC solar radiation beam before it is transmitted to the optic fibers bundles inside the HC light pipe. In fact, this spectral and thermal conditioning of the HC solar radiation beam reduces the thermal load in the LEC stack and it also improves the light-to-electricity conversion by significantly increasing the proportion of useful solar radiation spectrum accessing the PV cells following the removal of the said UV & IR radiations.

The collected HC sunlight is directed into an optical fiber bundle, which is a suitable light transmission medium (commonly called “light pipe”). Although all types of fiber optic cable are highly efficient (i.e., minimal attenuation), conventional plastic fiber would be suitable for obvious economic reasons unless fused silica or other high performance fibers would be specifically beneficial to a particular application. While the optical fiber may be bundled or solid core, bundled fiber would be suitable for its increased flexibility. Other types of light transmission media, such as hollow light pipes coated with highly reflective material may also be used, particularly in applications where short light transmission lines would be used. The HC light pipe according to the present invention transmits HC solar radiation to a number of LD panels placed inside the LEC stack assembly. The LD panels have the same shape and size as the PV panels and they ensure an even HC sunlight distribution over their entire light-emitting zone for maximum illumination of the PV panels inside the stack.

One feature of the invention is the LEC cell, which represents the core of the CPV stack assembly. A basic single LEC cell includes one LD panel receiving a portion of the solar radiation from the solar concentrator, and one PV solar panel adjoining the said LD panel; the HC solar radiation reaching the LD panel is evenly distributed on its active light-emitting side facing the said PV panel. Alternatively, a double-sided LD panel is capable of emitting solar radiation evenly on both the front side and the backside of the said LD panel. The combination of a double-sided LD panel positioned between two opposing PV panels creates a double LEC cell, which has a significantly increased solar energy harvesting capability, according to the experimental results, produced during testing by the inventors. More details on the LEC cells will be provided below.

The LEC cells are put together in a stack configuration inside a housing enclosure, to protect them from the elements and from damage during handling and operation. This arrangement allows for flexibility in design, construction and integration of the LEC stack assembly with a solar collection/concentration system to produce a compact Concentrated PV solar power stack system. The system design provides for a reduced number of LEC cells to deliver electrical power outputs to specific applications at lower costs. The said LEC stack placed inside a housing enclosure provides for a controlled operating environment of the PV panels (i.e., stable dry conditions—constant temperature and humidity) that eliminates the need for expensive weatherproof encapsulation of the PV panels. In addition, the LEC stack system has provisions for adequate spectral cooling/heat sink capabilities, which allows the system to run constantly at maximum efficiency.

These aspects and embodiments of the present invention will now be described in greater detail.

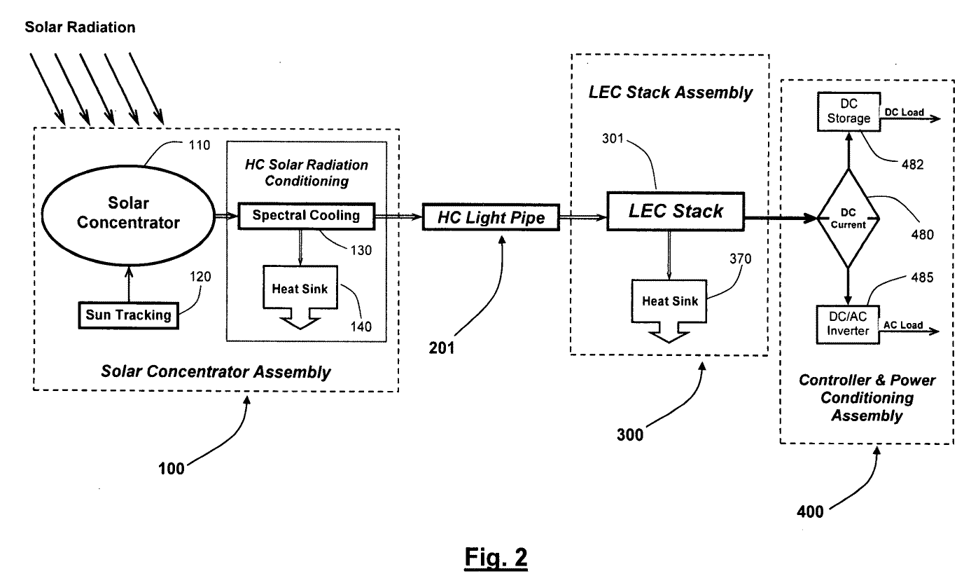

FIG. 2 shows the four assemblies that make up the concentrated PV solar power stack: the solar concentrator assembly at 100, the HC solar radiation transmission light pipe at 201, the LEC stack assembly at 300 and the controller & power conditioning assembly at 400. Each of these four assemblies will be briefly introduced below, with respect to their functional roles within the overall system operation as presented in FIG. 2.

The solar concentrator assembly 100 includes at least one solar concentrator panel indicated generally at 110, a sun tracking system 120 (which may not be needed on some types of solar concentrators), and a HC solar radiation beam spectral & thermal conditioning system represented by a combination of cooling systems including a spectral cooling system indicated at 130, as well as a passive and/or an active heat sink system indicated generally at 140. To achieve high performance, solar concentrators should have at least some type of accurate sun tracking, a high concentration ratio (i.e., 500× or more suns), a reduced focal distance (thus, reduced weight) and effective cooling of the HC solar radiation transmitted to the LEC stack system. One feature of the cooling system in the solar concentrator assembly of the present embodiment is the inclusion of the spectral cooling 130, in conjunction with the use of passive and/or active heat sink 140—as previously indicated, spectral and thermal conditioning of the HC solar radiation beam reduces the thermal load in the LEC stack by increasing the portion of useful radiation waveband directly available to the PV panel for direct light-to-electricity conversion.

The HC transmission light pipe 201 consists of hundreds of optic fibers packaged in a number of bundles connecting the solar concentrator assembly to each individual LD panel inside the LEC stack. The optic fiber bundles are routed through a flexible conduit to form a light pipe that can vary from ½ inch to over 2 inch in diameter (i.e., 12 mm-50 mm in diameter).

The LEC stack assembly at 300 includes the LEC stack 301 and the related heat sink devices generally indicated at 370. The core of the LEC stack is the light-to electricity-conversion (LEC) cell. Cooling fins on the supporting backs of the PV panels provide adequate heat sink capabilities within the LEC cells. The LEC cells are placed in a PV stack configuration inside a housing enclosure to protect them from the elements and from damage during handling and operation.

The controller and power conditioner assembly 400, representing the BOS (i.e., a DC-DC controller 480, a battery bank 482, and a DC-AC inverter 485), collects and stores the electricity generated by all PV panels inside the stack, to be delivered as regulated electric power (at various DC and/or 120V AC voltage) to the consumers. In smaller applications, the BOS may be incorporated inside the LEC stack housing enclosure. For larger applications, the BOS may be provided as a stand-alone system matching the rated power of the respective concentrated PV solar power stack system.

Detailed information with respect to key components that make up the compact LEC stack system according to the present invention will be provided in the following paragraphs.

In practice, a typical solar concentrator panel according to this embodiment might have a solar concentration range of 500× or more suns, a size range of 1 m² to 3 m², adequate heat management capabilities (including spectral cooling) and a lightweight construction for portability and ease of installation. Solar concentrators known to the art may utilize in their construction either sunlight reflectors (such as the point-focus dishes) or lens concentrators (such as point-focus Fresnel lens), in combination with other optical devices. Selection of either type of solar collection/concentration assembly for this application would be, besides its technical performance and reliability, subject to its commercial availability and economics. The current fast expanding market of concentrated PV solar power applications and also in building integrated hybrid solar lighting systems offer a number of products that meet the aforementioned specifications for the solar concentrator assembly according to this invention. Here are a few examples:
Sunlight Direct from Knoxville, Tenn. (USA) produces, under license, a rooftop solar concentrator for solar hybrid lighting applications. The HSL technology uses a 4-ft-wide dish and secondary mirror that track the sun throughout the day focusing the sunlight onto flexible light pipes having 127 optical fibers. The IR and UV energy from the concentrated sunlight is separated before it travels into the buildings.
Green & Gold Energy, an Australian company, specializes in solar concentrators for high performance PV cells. Their SunBall™ solar concentrating module uses multi element non focusing Fresnel lens and has a passive heat sink system. The module has 1.13 m diameter and produces a sunlight concentration in the order of 500× suns.
Soliant Energy, Inc. from Pasadena, Calif., designs and manufactures concentrating photovoltaic modules for commercial applications. The Soliant design combines both lenses and mirrors to create a more compact system inside aluminum troughs, each about the width and depth of a gutter with a clear acrylic lid on top. These troughs are mounted inside a rectangular frame using a fully integrated tracking system. Inside each trough, a strip of silicon photovoltaic material runs along the bottom and is exposed to a concentrated solar radiation in the order of 500× suns.
Parans from Gothenburg, Sweden, specializes in solar hybrid lighting systems. The new Parans SP2 solar concentrator is a 1 m² square-shaped panel fixed-mounted on roofs or facades of the buildings. Inside the panel, 64 Fresnel lenses move uniformly around their axis, tracking and concentrating sunlight with a wide acceptance angle of 60 degrees, thus forming a 120 degrees active cone. The Parans SP2 design ensures that the sunlight is efficiently concentrated into optical fibers placed underneath each lens and transmitted inside the building to hybrid lighting fixtures. The system has dichroic filters that remove the IR and UV energy from the concentrated sunlight before it travels into the buildings.
CoolEarth from Livermore, Calif., has a new CPV technology involving inflatable mirrors (half the thickness of a piece of paper and four-hundred times cheaper than conventional solar mirrors) 2 meters across and, depending on the sunlight source, capable to produce 500 W-1 kW electrical power outputs. Instead of large expensive solar panels or costly concentrating mirrors, the company is using balloons made of metallized plastic films. Half of the balloon is transparent, letting the light in to be concentrated into a small high-efficiency solar panel by the concave interior. Such concentrated PV systems are supported by cables on poles, leaving the ground below clear with limited or no environmental impact.

It is one objective of the invention to create a compact concentrated PV solar power stack system (i.e., a LEC stack system) by combining a plurality of PV solar panels with a plurality of LD panels positioned in a stack configuration. FIG. 3A shows a schematic diagram of the concentrated PV solar power stack system according to the present invention having, in the callout represented in FIG. 3B, an isometric view detailing the LEC Stack assembly configuration (illustrated without the housing enclosure). For purposes of illustration, FIG. 3B shows a 10-cell LEC stack having double LEC cells. Each double LEC cell generally indicated at 311 (in an exploded view) and at 312 (in its closed operating setting), comprises one double-sided LD panel 222 positioned between two opposing PV solar panels 321, on each of the outer side of the said solar panels. The HC solar radiation from the solar concentrator assembly 100 is transmitted through the optic fiber bundles inside the HC light pipe 201 to an optical connections manifold 212 coupled to the said LD panels 222. The optical connection between each individual optic fiber bundle of the said manifold and its designated LD panel is indicated generally at 215. The said LD panel illuminates the adjoining PV panels inside the LEC cell to ensure maximum light-to-electricity conversion. Conventional electrical cables 381 interconnect individual LEC cells inside the stack system into a power circuit of the desired current voltage and power, while the electrical cables 481 connect the LEC stack to the BOS to deliver regulated DC/AC electrical power to consumers (i.e., a DC solar charge controller 480, a battery bank 482, and an inverter 485).

As previously indicated, the LD panels represent the source of HC solar illumination for the PV panels inside the LEC stack. Suitable LD panels may be created by using optic fibers and combinations of reflective and refractive optical devices. Two distinctive embodiments of LD panels are described: A) an optic fiber LD (OFLD) panel, and B) a light-box (LB) panel—either of these LD panels can be incorporated in the construction of the single LEC cells according to this invention. The OFLD panel can also be used in the construction of the double LEC cells without any modifications.

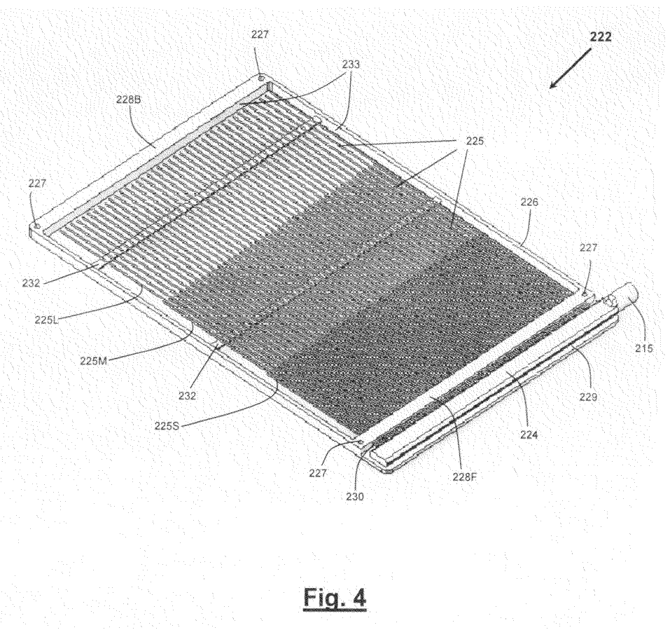

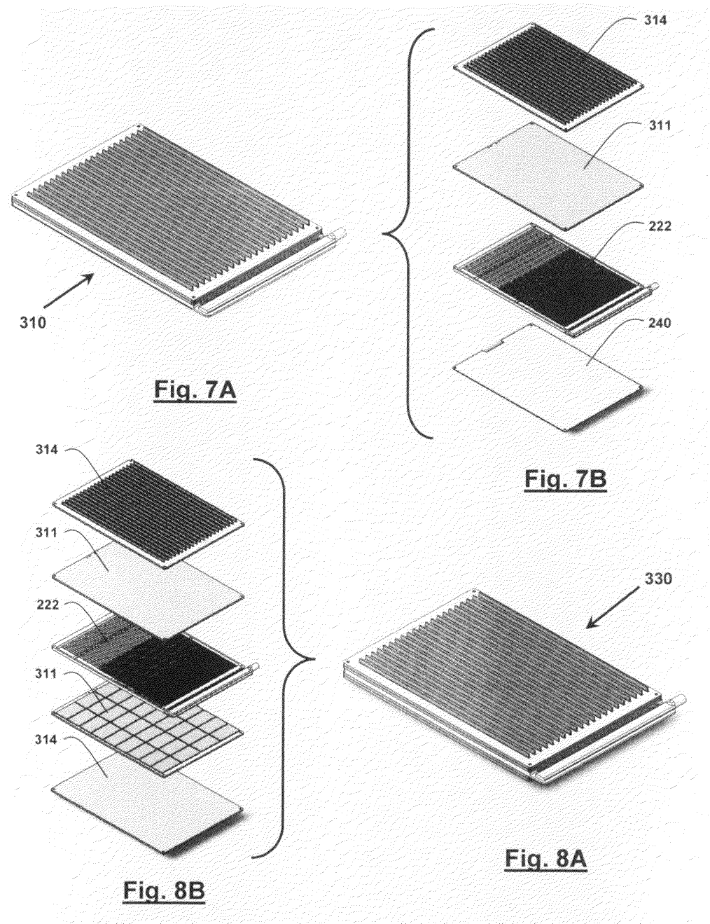

One exemplary embodiment of this invention that contains the OFLD panel is generally indicated at 222 in FIG. 4. The OFLD panel functions by ways of releasing sidelight that escapes from the unsheathed areas of the optic fibers evenly distributed inside the light-emitting zone of the LD panel. The OFLD panel includes three basic components: i) a supporting frame 226, ii) a plurality of optic fibers 225, and iii) an optical inlet port 215. The frame 226 is relatively thin, for example ½ inch thick or less (i.e., 10-12 mm) and is made of plastic. The said frame extends around the perimeter of the said OFLD panel having the front and back ends 228F and 228B, respectively, wider to include four mounting holes 227 to assemble the LD panel in a LEC cell configuration, as shown later in FIG. 7 and FIG. 8. The inside walls of the said frame indicated generally at 233 facing the light-emitting zone of the said OFLD panel are covered with highly reflective material. The optical inlet port 215 has an optical connector inside it, which holds the proximal end of the optic fibers 225 as they extend out of the said optical connector bending at 90 degrees before protruding a plurality of guiding holes 230 bored in an equidistant parallel pattern into the front end of the frame 228F. The said optical inlet port and the portion of the curving optic fibers extending towards the guiding holes are placed on a supporting base 229 which extends outwards over the entire width of front end of the said frame, and protected from damage during installation and operation by a plastic cover 224.

The optic fibers protruding the said guiding holes spread out evenly in a parallel pattern into the light-emitting zone of the OFLD panel demarcated by the inside contour of the said frame 226 having their distal ends directed towards the back end 228B of the frame. The said distal segments of the optic fibers are held in place by adhesive reflective bands 232, anchored at each end to the respective lateral sides of the frame. The optic fibers used in this application are conventional core & cladding optical fibers, which encourage light transmission with minimal losses by ways of total internal reflection (TIR). The light passing through can be extracted in sections of the said optic fibers having the cladding removed thus creating light-emitting areas.

It is known that the light extraction rate from optic fibers declines monotonically and quite rapidly down the length the said light-emitting areas towards their distal ends. Therefore, to provide for a controlled and evenly distributed illumination of the entire light-emitting zone of the said OFLD panel, it is helpful to optimize the light-emitting surface area of individual optic fiber for maximum light extraction while maintaining the same-length of the said light-emitting area on all optic fibers.

For purposes of illustration, FIG. 4 shows a OFLD panel of rectangular shape, about 12 inch long (i.e., about 30 cm) and 8 inch wide (i.e., about 20 cm), using 120 optic fibers, each about 1/32 inch in diameter (i.e., about 1 mm). The optic fibers, in this particular instance, are separated in three sets of equal number of optic fibers but each set is of a different length, as follows: 225S—indicate the short set of optic fibers having the cladding removed for their full length which creates the proximal illumination band representing ⅓ of the light-emitting zone across the said OFLD panel; 225M—indicate the medium set of optic fibers having the cladding removed from the level marked by the open ends of the short optic fibers 225S to the open end of the said medium optic fibers, which creates the central illumination band representing ⅓ of the light-emitting zone across the said OFLD panel; 225L—indicate the long set of optic fibers having the cladding removed from the level marked by the open ends of the medium optic fibers 225M to the open end of the said long optic fibers, which creates the distal illumination band representing ⅓ of the light-emitting zone across the said OFLD panel. In practice, the OFLD panels according to this invention may have different shapes and sizes matching the shape and size of the pairing PV panel(s) in the LEC cell. The total number of the optic fibers necessary for one OFLD panel according to this invention depends on several factors including the actual size of the said OFLD panel and the intensity level of the solar radiation produced by the light-emitting zone of the said OFLD panel, in addition to the actual size and optical characteristics of the said optical fibers. Therefore, it is critical that the partition of the said optic fibers in any N sets of same-length (e.g., N=2−10) be in strict correlation to equal light-emitting surface areas on all said optic fibers for homogeneous illumination of the entire light-emitting zone of the said OFLD panel.

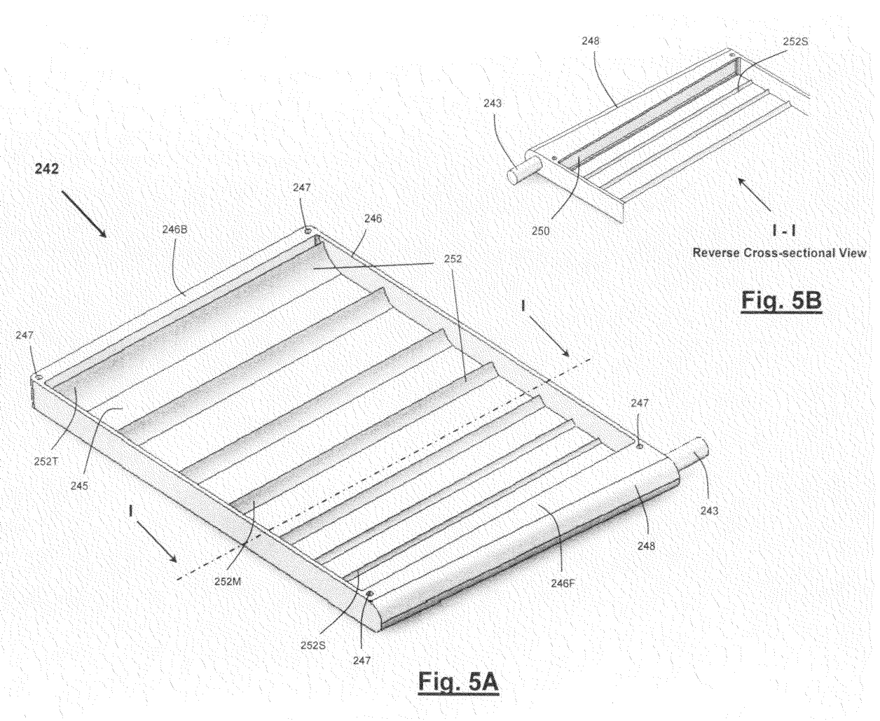

FIG. 5A illustrates another exemplary embodiment of this invention including the LB panel generally indicated at 242 representing an alternative solution for a one-sided LD panel. The LB panel functions as a substantially homogeneous light-emitting panel which is releasing the solar radiation, received via the HC light pipe, over its light-emitting zone by using a combination of lens, right angle prisms and reflective elements. FIG. 5A shows an isometric view of the LB panel according to this invention that includes three basic components: i) a supporting frame 246, ii) a floor plate 245 having a plurality of pyramidal reflectors 252 cast into the said floor plate in fixed angled positions to increase the total reflective area against the incoming sunlight flux, and iii) at least, one optical inlet port indicated generally at 243, directing HC solar radiation into the light-emitting zone of the said LB panel.

The inside walls of the said frame facing the floor plate 245, and the said floor plate including the pyramidal reflectors are covered with highly reflective material to cause maximum reflection of the incoming sunlight flux over the entire light-emitting zone of the said light-box panel. The frame 246 is relatively thin, for example one inch thick or less in height (i.e., 20-25 mm) and is made of plastic. The said frame extends around the perimeter of the panel 242 in a rectangular shape having the front and back ends 246F and, respectively, 246B, wider to include four mounting holes 247 to assemble the LB panel in a LEC cell configuration. The front end of the said frame expands outwards beyond its respective mounting holes and over the entire length of the front end to provide the housing for the optical inlet port 243.

The pyramidal reflectors 252 are cast in the floor plate in an elongated structure of the same height from one lateral side to the other of the said frame and oriented transverse relative to the incoming sunlight beam. These pyramidal mirrors form raised reflective angled profiles, which produce the scattering of the incoming light evenly over the area under their reflective effect. Precise parallel positioning of the said pyramidal reflectors and increase in their surface area facilitate accurate reflection geometry for even light distribution over the entire light-emitting zone of the LB panel, as they lay taller more distal to the sunlight injection end of the said LB panel and illustrated in FIG. 5B from the shortest pyramidal mirror 252S closest to the light injection port to the medium reflectors 252M and ending with the tall reflectors 252T.

The optical inlet port detailed in the reverse cross-sectional view in FIG. 5 comprises an optical connector 243 coupled to the HC light pipe to receive solar radiation, a highly reflective housing 248 and an optical window 250 injecting the HC radiation flux into the light-emitting zone of the LB panel. The said housing for the optical inlet port is a tapered hollow light pipe having a full side opened as a rectangular optical window 250 sideways towards the light-emitting zone of the LD panel. For the purpose of illustration, the said housing is a tapered trough less than one inch wide and placed sideways to have its opened side serve as the rectangular optical window towards the light-emitting zone of the LD panel. The housing has the wall opposite to the optical window tapered from the large cross-section area at the optical connector end to the smallest cross-section area at the distal end of the said housing. The angle of the tapered wall allows for the HC sunlight entering the said housing to be evenly averaged and distributed across the right angle prisms located in the optical window into the entire light-emitting zone of the LB panel. As the light flux radiates into the light-emitting zone of the LB panel, it comes across the increasingly higher pyramidal reflectors cast in floor plate to produce an even illumination. Installing two optical inlet ports on the either end of the LB panel can further increase the performance of the said LB panel.

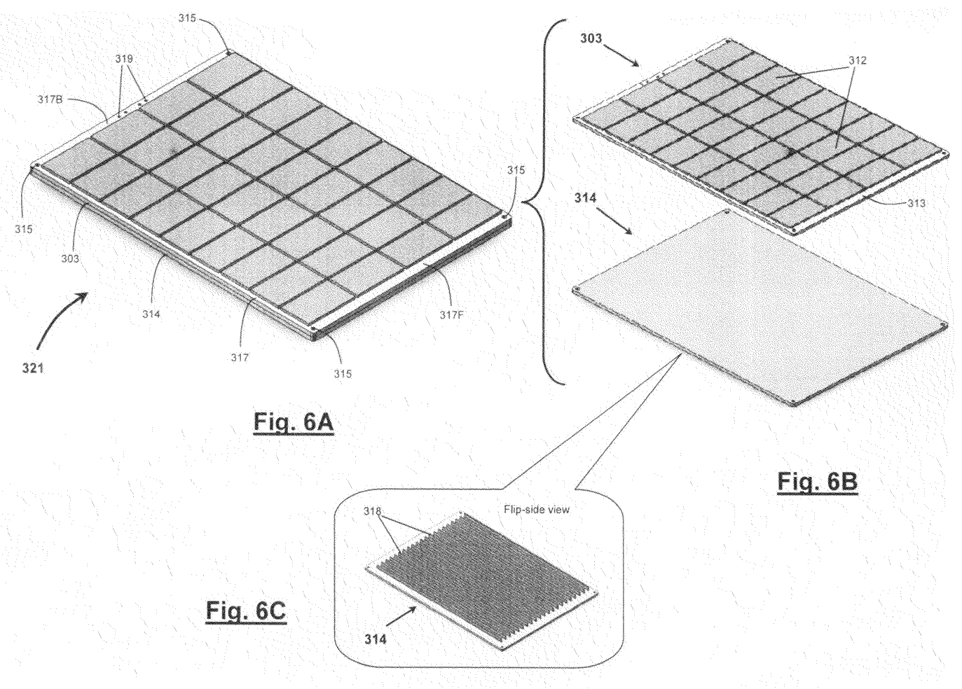

An embodiment of the PV panel with a cooling plate is generally illustrated in FIG. 6A at 321 and detailed in an exploded isometric view of FIG. 6B showing a conventional PV panel 303 and a cooling plate with fins 314 making contact with the backside of the said PV panel. The PV panel 303 has a plurality of photovoltaic cells 312 electrically interconnected on their backside to produce at the external electrical connectors 319 of the said PV panel a power circuit of the desired current voltage and power. The said photovoltaic cells 312 and their electrical interconnections are mounted on a supporting back plate 313, which provides mechanical strength and high thermal conductivity to the PV panel. The back plate 313 extends around the perimeter of the panel having the front side and backside indicated at 317F and 317B, respectively, wider to include four mounting holes 315 to assemble the PV panel in a LEC cell configuration. The edges 317 around the perimeter of the PV panel are recessed matching the shape and size of the corresponding LD panel frame. The recessed edges around the said PV panel perimeter facilitate complete enclosure of its photovoltaic cells 312 within the active light-emitting zone demarcated by the LD panel frame, when the PV panel is placed on top of the said LD panel in the mounting position in the LEC cell.

The cooling plate having attached on its underside a plurality of cooling fins shown at 318 in FIG. 6C and facing outwardly, the PV plate constitutes the heat sink system of the said PV panel. With high efficiency PV panels generating large amounts of heat during the direct light-to-electricity conversions, the cooling plate can be extended in one or more directions outwards to the perimeter of the said PV panel to increase the heat sink area. Should highly intensive cooling be necessary, the said cooling plate extensions may be incorporated in various active cooling systems (e.g., forced air cooling, water cooling, etc.). The cooling plate and the supporting back plate of the PV panel are made of heat conductive materials such as aluminum or the like. The PV panels currently available on the market come in various shapes and sizes and, consequently, they control the shapes and sizes of the LD panels and, therefore the shape and size of the LEC stack assembly. For higher power outputs, as the electric power output of the LEC stack is directly influenced by the performance of the PV panels inside it, high efficiency MJ PV panels may be utilized for this application to maintain the unique features of the compact LEC stack system according to this invention.

As previously indicated, a basic single LEC cell includes one one-sided LD panel receiving a portion of the solar radiation from the solar concentrator, and one PV panel that lies on top the said LD panel; the HC solar radiation reaching the LD panel is evenly distributed on its only light-emitting side that is facing the said PV panel. Either of the OFLD panel or the LB panel can be incorporated in the construction of the single LEC cells according to this invention. FIG. 7A shows an isometric view of a single S-LEC cell indicated generally at 310, having a OFLD panel 222, a highly reflective back plate 240, and a PV panel 311 facing its photovoltaic cells downwards the top side of the said OFLD panel, illustrated in an exploded isometric view of FIG. 7B. The back plate 240 positioned under the OFLD panel assembles the configuration of the one-sided LD panel and also serves as a supporting structure for the single LEC cell. More importantly, the said back plate acts as the reflective floor of the OFLD panel that facilitates full illumination of the PV panel from both, the sunlight emitted upwards by the optic fibers directly to the PV panel as well as the light scattered downwards and reflected back toward the said PV panel. It is critical that the LEC cell assembly as indicated at 310 has the OFLD panel tightly covered top, by the solar panel, and bottom, by the back plate to ensure full entrapment of the sunlight inside the respective LEC cell and avoid unnecessary light losses. Cooling fins on the backside of the PV panel remove the heat built-up during the LEC cell normal operation. An alternative construction of a single S-LEC cell according to this invention can utilize a LB panel 242 to replace the OFLD panel 222 and the back plate 240 shown in FIG. 7B. This option may be more effective in harvesting sunlight for maximum direct light to electricity conversions, in the smaller LEC stack configurations.

The OFLD panel can be used in the construction of the double LEC cells without any modifications. FIG. 8A illustrates a double D-LEC cell in its normally closed operating setting, generally indicated at 330. The exploded isometric view in FIG. 8B shows the make-up of the D-LEC cell having a OFLD panel 222 receiving a portion of the HC solar radiation from the solar concentrator, and two PV panels 311 with their respective cooling plates 314, one of the PV panels facing downwards the top side of the said OFLD panel and the second PV panel positioned under the OFLD panel facing its bottom side replacing the back plate 240 of the S-LEC cell illustrated in FIG. 7B. In this configuration, the D-LEC cell has the doubled the heat sink capacity of the two cooling plates 314 and increased sunlight harvesting capability for maximum light to electricity conversion.

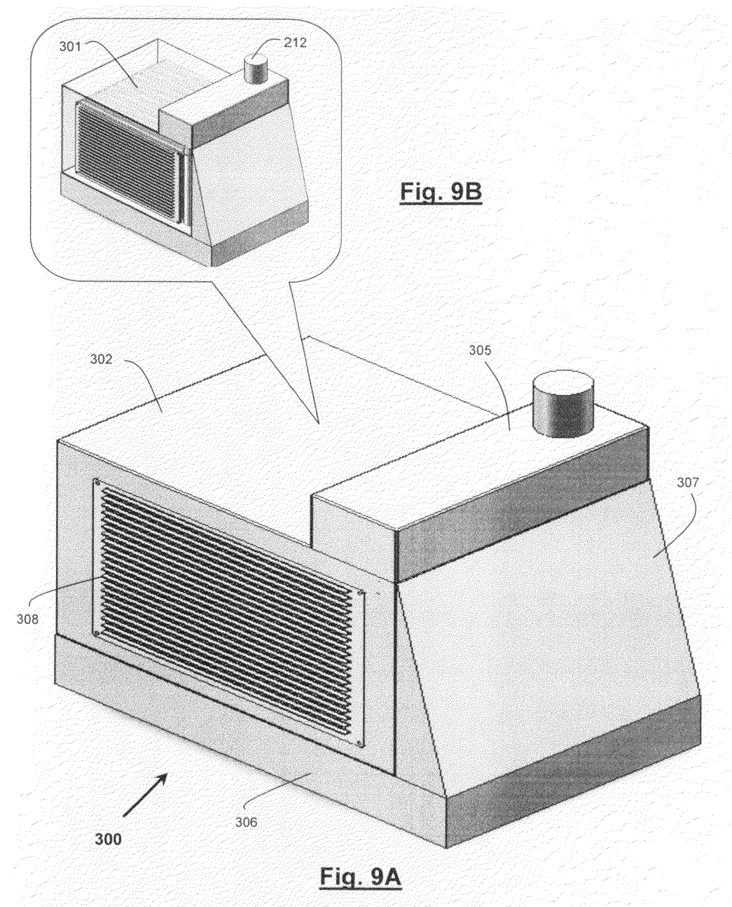

FIG. 9A shows an embodiment of a LEC stack according to aspects of this invention, representing a PV solar panels array arranged in a tri-dimensional, compact and modular configuration in a housing enclosure, and having the said PV solar panels exposed to the solar radiation remotely collected, transmitted and distributed to the LD panels placed inside the said housing enclosure adjacent to each of the said PV panels to allow for direct light-to-electricity conversion. For purposes of illustration, in FIG. 9A is disclosed a LEC stack assembly indicated generally at 300 having a housing structure divided in at least four compartments, a 10-cell D-LEC/OFLD stack 301 and a manifold of optical connectors indicated generally at 212, detailed in the isometric view of FIG. 9B. The said stack 301 is enclosed in the main compartment 302 of the said housing structure, having provided louvers 308 on the sidewalls to allow for cooling air circulation inside the said main compartment. All the optical connections between the LD panels inside the stack and the HC light pipe done through the optical connectors manifold are placed in the optical connectors compartment 305 of the said housing structure. The electrical interconnections of all PV panels inside the stack and the electrical connection of the stack with the controller are located in the electrical compartment 306 of the said housing structure, while the controls compartment 307 of the said housing structure contains the required instrumentation for monitoring and control of the PV stack assembly.

While the embodiment of the LEC stack assembly illustrated in FIG. 9A and FIG. 9B show the LEC cells and the respective PV panels and LD panels in a rectangular shape and stacked in a horizontal linear configuration, the said PV panels and LD panels may have any other shapes (i.e., square, circular, 2D-irregular shape, etc.) as they would fit better certain applications, and the said LEC stack may also by configured in a vertical linear pattern or in a radial stack configuration as it would be best fit for specific applications.

The total number of LEC cells (i.e., the actual number of PV panels and LD panels) in a LEC stack is determined by the design capacity of the solar power system. The actual size of a LEC stack for a given electric power output is determined by the type and dimensions of PV the panels employed in the construction of solar power assembly according to this invention—that is, for the same power output and having the same size of the PV panels, a MJ LEC stack (i.e., non-Si based MJ PV cells @ 40-42% LEC efficiency) would be about 1.5 times smaller than a CPV stack (i.e., Si-based MJ PV cells @ 25% LEC efficiency) and about 2.5 times smaller than a regular Si-based PV stack (i.e., 12-18% LEC efficiency).

In another embodiment of this invention, the LEC stack system may be employed for producing electricity in conjunction with the use of the intense beam of sunlight conducted through buildings by means of tubular mirrors, optic fibers, prisms and various geometrically-shaped mirrors to divide, channel, distribute, deflect, reflect and diffuse the said sunlight beam for hybrid solar lighting inside the said buildings.

What is claimed is:

1. A Concentrated PV solar power stack system for generating electricity through direct high concentration sunlight-to-electricity conversion, said power system comprising:
(a) a solar concentrator assembly that provides HC solar radiation having at least one solar concentrator, at least one sun tracking device and at least one combination of spectral and thermal conditioning means of the said HC solar radiation;
(b) a HC light pipe having a plurality of optic fiber bundles that transmit HC solar radiation and the said HC light pipe having two ends, one said end coupled to said solar concentrator assembly;
(c) a LEC stack assembly having a plurality of LEC cells enclosed in a housing structure, each said LEC cell having one light-emitting LD panel and at least one direct light-to-electricity generating PV panel positioned adjacent each said LD panel, and each of the said LD panel having at least one optical inlet port coupled by optical connections to the other said end of said HC light pipe, and
(d) a controller & power conditioning assembly for collection, storage and distribution of electricity generated by each said LEC cell having a at least one DC controller, at least one battery bank, at least one DC-AC inverter, at least one control panel and two electrical connections, one said electrical connection coupled to the interconnect wires connecting each said PV panel of each said LEC cell and the other said electrical connection coupled to at least one load.

2. A concentrated PV solar power stack system as set forth in claim 1 wherein the said solar concentrator assembly includes a combination of geometrically-shaped mirrors interconnected in a least one-stage arrangement to yield high concentration ratios of solar radiation.

3. A concentrated PV solar power stack system as set forth in claim 2 wherein the combination of geometrically-shaped mirrors includes at least one:
(a) parabolic mirror;
(b) cone-shaped mirror;
(c) tetrahedrally-shaped mirror, or/and
(d) through-shaped mirror;
interconnected in a least one-stage arrangement to yield high concentration ratios of solar radiation.

4. A concentrated PV solar power stack system as set forth in claim 1 wherein the said solar concentrator assembly includes a combination of refractive optical devices interconnected in at least one-stage arrangement to yield high concentration ratios of solar radiation.

5. A concentrated PV solar power stack system as set forth in claim 4 wherein the combination of refractive optical devices includes at least one:
(a) lens;
(b) prism, and/or
(c) dichroic device,
interconnected in a least one-stage arrangement to yield high concentration ratios of solar radiation.

6. A concentrated PV solar power stack system as set forth in claim 1 wherein the said solar concentrator assembly includes at least a combination of geometrically-shaped mirrors and at least one combination of refractive optical devices interconnected in a multi-stage arrangement to yield high concentration ratios of solar radiation.

7. A concentrated PV solar power stack system as set forth in claim 1 wherein the said solar concentrator assembly includes at least one combination of spectral and thermal conditioning of the HC solar radiation means comprising:
(a) at least one combination of spectral cooling devices to remove the UV and IR radiations from the said HC solar radiation;
(b) at least one combination of heat sink devices to cool down the said HC solar radiation to optimal temperature levels for proper PV panels operation.

8. A concentrated PV solar power stack system as set forth in claim 1 wherein the said LEC stack assembly having a plurality of LEC cells and a housing structure divided in at least four compartments, having the said LEC cells placed inside a first compartment, the said optical connections to the said HC light pipe placed in a second compartment, the said electrical interconnect wires located in a third compartment and the said control panel installed in a fourth compartment of the said housing structure.

9. A concentrated PV solar power stack system as set forth in claim 8 wherein the said plurality of LEC cells are assembled in a stack configuration, secured by fasteners and having the said LEC stack placed inside the said first compartment of the said housing structure.

10. A concentrated PV solar power stack system as set forth in claim 8 wherein each of the said LEC cell includes one LD panel having a one-sided light-emitting area, and one PV solar panel adjoining the light-emitting side of the said LD panel in a closed PV panel-LD panel paired pattern to form a single S-LEC cell.

11. A concentrated PV solar power stack system as set forth in claim 8 wherein each of the said LEC cell includes one LD panel having a double-sided light-emitting area and two opposing PV panels positioned adjacent on each of the outer side of the said LD panel in a closed PV panel-LD panel-PV panel paired pattern to form a double D-LEC cell.

12. A concentrated PV solar power stack system as set forth in claim 8 wherein the said plurality of LEC cells mounted in the said stack configuration having the said LD panels of the said LEC cells receive HC solar radiation, and the said HC solar radiation is remotely generated by the said solar concentrator assembly and transmitted through the said optic fiber bundles of the said HC light pipe to a manifold of optical connectors coupled to the said LD panels inside the said second compartment of the said housing structure.

13. A concentrated PV solar power stack system as set forth in claim 8 wherein the said plurality of LEC cells mounted in the said stack configuration having the said PV panels of the said LEC cells electrically interconnected inside the said third compartment of the said housing structure to produce a power circuit of the desired current voltage and power and having the said power circuit connected to the said controller.

14. A concentrated PV solar power stack system as set forth in claim 10 wherein the said one-sided LD panel includes a OFLD panel having a plurality of optic fibers with controlled light-emitting areas at their distal ends evenly distributed over the entire light-emitting zone of the said OFLD panel, and a reflective floor panel redirecting the scattered light from the said light-emitting areas of the said optic fibers back to the light-emitting side of the said OFLD panel.

15. A concentrated PV solar power stack system as set forth in claim 14 wherein the said OFLD panel comprising:
(a) a supporting frame extending around the perimeter of the said one-sided LD panel having the front and back ends wider to include the four mounting holes to assemble the said one-sided LD panel in the said single LEC cell inside the said holding frame structure of the said housing structure;
(b) a plurality of optic fibers having two ends, the proximal end of the said optic fibers being bundled up in an optical connector and the distal end of the said optic fibers protruding a plurality of guiding holes placed equidistantly in a parallel pattern into the front end of the said supporting frame and extending throughout the light-emitting zone of the said one-sided LD panel demarcated by the inside contour of said supporting frame; and
(c) an optic fiber inlet port having the said optical connector of the said plurality of optic fibers coupled to the said manifold of optical connectors of the said HC light pipe to receive HC solar radiation from said solar concentrator assembly.

16. A concentrated PV solar power stack system as set forth in claim 15 wherein the said plurality of optic fibers having their distal ends inside the said light-emitting zone of the OFLD panel directed in a parallel equally spaced pattern towards the back end of the said supporting frame, and having precisely controlled light-emitting areas formed by removing the cladding from preset equal lengths at the distal ends of the said optic fibers.

17. A concentrated PV solar power stack system as set forth in claim 16 wherein the said plurality of optic fibers having equal lengths of light-emitting areas are divided in N sets of same-length and each set is spread evenly across the entire width of the said light-emitting zone (e.g., N=2-10) to form N illumination bands stretching in a direction transverse to the said optic fibers and positioned next to each other to cover the entire said light-emitting zone from the front end to the back end of the said OFLD panel.

18. A concentrated PV solar power stack system as set forth in claim 10 wherein the said one-sided LD panel includes a LB panel which functions as a light-emitting panel using a combination of refractive and reflective elements to release evenly the solar radiation over its light-emitting side.

19. A concentrated PV solar power stack system as set forth in claim 18 wherein the said LB panel comprising:
(a) a supporting frame extending around the perimeter of the said one-sided LB panel having the front and back ends wider to include the four mounting holes to assemble the said one-sided LB panel in the said single LEC cell inside the said holding frame structure of the said housing structure;
(b) a floor plate having a plurality of pyramidal reflectors cast into the said floor plate in an elongated structure pattern of the same height from one lateral side to the other of the said frame and oriented transverse relative to the incoming sunlight beam; and
(c) at least, one optical inlet port directing solar radiation into the light-emitting zone of the LB panel.

20. A concentrated PV solar power stack system as set forth in claim 19 wherein the said pyramidal reflectors form raised reflective angled profiles as they lay taller more distal to the optical inlet port of the said LB panel in a precise parallel pattern to produce the scattering of the incoming light evenly over the area under their reflective effect to ensure accurate reflection geometry for even light distribution over the entire light-emitting zone of the LB panel.

21. A concentrated PV solar power stack system as set forth in claim 19 wherein the said optical inlet port includes a highly reflective housing having tapered walls and a rectangular optical window with right angle prisms placed sideways to direct the HC sunlight entering the said optical inlet port towards the light-emitting zone of the said LB panel.

22. A concentrated PV solar power stack system as set forth in claim 21 wherein the said housing is a trough placed sideways having its opened side oriented towards the rectangular optical window and the wall opposite to the said optical window tapered in an angle that allows for the HC sunlight entering the said housing to be evenly averaged and distributed across the right angle prisms located in the optical window into the entire light-emitting zone of the LB panel.

23. A concentrated PV solar power stack system as set forth in claim 11 wherein the said double-sided LD panel includes a OFLD panel having a plurality of optic fibers with controlled light-emitting areas at their distal ends evenly distributed over the entire light-emitting zone of the said OFLD panel.

24. A LEC stack assembly for generating electricity through direct light-to-electricity conversion of intense beam of sunlight having a plurality of LEC cells enclosed in a housing structure in a horizontal or vertical linear stack configuration, each said LEC cell having one light-emitting LD panel and at least one PV panel positioned adjacent each said LD panel.

25. A LEC stack assembly for generating electricity through direct light-to-electricity conversion of intense beam of sunlight having a plurality of LEC cells enclosed in a housing structure in a radial stack configuration, each said LEC cell having one light-emitting LD panel and at least one PV panel positioned adjacent each said LD panel.
